(19) United States
(12) Patent Application Publication
(10) Pub. No.: US 2015/0140758 A1
(43) Pub. Date: May 21, 2015

(54) METHOD FOR FABRICATING FINFET ON GERMANIUM OR GROUP III-V SEMICONDUCTOR SUBSTRATE

(71) Applicant: Peking University, Beijing (CN)

(72) Inventors: Ru Huang, Beijing (CN); Jiewen Fan, Beijing (CN); Xiaoyan Xu, Beijing (CN); Jia Li, Beijing (CN); Runsheng Wang, Beijing (CN)

(21) Appl. No.: 14/400,511

(22) PCT Filed: Jul. 8, 2013
(86) PCT No.: PCT/CN2013/079018

§ 371 Date: Nov. 11, 2014

(30) Foreign Application Priority Data
Sep. 5, 2012 (CN) 201210326467.6

(51) Int. Cl. H01L 29/66; H01L 21/027; H01L 21/321; H01L 21/033; H01L 21/324; H01L 21/28; H01L 21/311; H01L 21/3105; H01L 21/285; H01L 21/02

(52) U.S. Cl. CPC H01L 29/66795; H01L 21/2855; H01L 21/28556; H01L 21/0277; H01L 21/3212; H01L 21/0228; H01L 21/324; H01L 21/28194; H01L 21/31111; H01L 21/31116; H01L 21/31055; H01L 21/02164; H01L 21/0217; H01L 21/0332
USPC 438/283

(57) ABSTRACT

The present invention provides a method for fabricating a FinFET on a germanium or group III-V semiconductor substrate. The process flow of the method mainly includes: forming a pattern structure for a source, a drain and a fine bar connecting the source and the drain; forming an oxide isolation layer; forming a gate structure, a source and a drain structure; and forming metal contacts and metal interconnections. The method may allow an easy fabrication of a FinFET on a germanium or group III-V semiconductor substrate, and the entire process flow is similar to a conventional silicon-based integrated circuit fabrication technology despite it is achieved based on the germanium or group III-V semiconductor material. The fabrication process is simple, convenient and has a short period. In addition, the FinFET fabricated by the above process flow has a minimum width that can be controlled to about 20 nm. The multi-gate structure can provide excellent gate control capacity, which is very suitable for fabricating an ultra-short channel device so as to further reduce the device size. Further, the FinFET fabricated by the present invention has lower power consumption.

### CROSS REFERENCE OF RELATED APPLICATIONS

The present application is a national stage application under 35 U.S.C. §371 of International Application No. PCT/CN2013/079018, filed Jul. 8, 2013, which in turn claims priority of chinese application No. 201210326467.6, filed on Sep. 5, 2012, the content of each of which is incorporated herein by reference in its entirety.

### FIELD OF THE INVENTION

The present invention refers to a method for fabricating a FinFET on a germanium or group III-V semiconductor substrate, referring to a field of ultra large-scaled integrated circuit fabrication technology.

### BACKGROUND OF THE INVENTION

Today's semiconductor fabrication technology is booming under a rule of Moore's law. The performance and integration intensity of the integrated circuits are increasingly increased, and the power consumption of the integrated circuits is decreased as much as possible. Therefore, the fabrication of a short channel device with high performance and low power consumption will become a focus of future's semiconductor production industry. After entering into a level of 22 nm technology node, a conventional planar field effect transistor has an increased leakage current. Further, a short channel effect, a drain induced barrier lowering (DIBL) effect are getting more severe, thereby it can not fit the development of the semiconductor fabrication. In order to overcome the above-mentioned problems, there emerge lots of new structured semiconductor devices, such as a Double Gate FET, a FinFET, a Tri-Gate FET, a Gate-all-around (GAA) Nanowire (NW) FET, etc, which are paid a wide attention. By means of a multi-gate structure, a capacity for a gate controlling a channel can be well enhanced, so that electrical field lines are difficult to reach a source by directly across the channel from a drain. As such, the drain induced barrier lowering effect can be greatly improved, the leakage current can be reduced, and the short channel effect can be well inhibited. Because of the excellent gate controlling capacity due to the gate structure, the channel is not necessary to be highly doped as a conventional planar field effect transistor to inhibit the short channel effect. The advantage of a lightly doped channel lies in that a reduction in mobility due to scattering is relieved, so that the mobility of the multi-gate device is greatly improved. Therefore, as a new structured device, the FinFET will be a very promising alternative capable of replacing the conventional planar field effect transistor.

Hasimoto et al. proposed a concept of “folded-channel MOSFETs” in the IEDM conference in 1998. In 1999, Heang et al. disclosed a FinFET with a channel length below 50 nm in the IEDM conference. This is the first time that a FinFET is successfully integrated onto a substrate using a conventional silicon process.

Hu et al. disclosed a structure and a fabricating method of a FinFET in U.S. Pat. No. 6,413,802. The FinFET is most easily to be formed on an SOI substrate. This process is simple, only requiring to etch a Fin bar on the top silicon layer of the SOI substrate, and then to perform a series of gate process, source/drain process and back-end processes for forming a dielectric layer and metal interconnections so as to form the FinFET. However, the FinFET has the following disadvantages: (1) the process cost is too high, since the SOI substrate is very expensive; (2) a source/drain lifting technology is required, otherwise an excessively large spreading resistance of the source/drain may lead to an excessively small on-current and a poor performance; (3) a body is not led out, and thus a threshold voltage can not be adjusted by a substrate bias effect. Forming a FinFET on a germanium or group III-V bulk substrate has the following advantages: (1) the process costs is low, since the FinFET is fabricated on the bulk substrate, which is much cheaper than the SOI substrate; (2) because of using the germanium or group III-V bulk substrate, the mobility of the device is high and thus a larger on-current may be obtained; (3) when the FinFET is fabricated on the bulk substrate, the body can be led out so that the threshold voltage can be adjusted by the substrate bias effect.

### SUMMARY OF THE INVENTION

An object of the present invention is to propose a method for fabricating a FinFET on a germanium or group III-V semiconductor substrate, which is compatible with a conventional silicon-based ultra large scaled integrated circuit fabrication technology.

The present invention can be achieved by the following technical solutions. A method for fabricating a FinFET on a germanium or group III-V semiconductor substrate includes the following steps:

a) forming a pattern structure for a source, a drain and a fine bar (a Fin bar) connecting the source and the drain

A main object of this step is to form the pattern structure for the source, the drain and the fine bar connecting the source and the drain in a hard mask by using an electron beam lithography process. A structure of the fine bar formed by using an electron beam lithography process may have a width of about 20-40 nm.

i. depositing a silicon oxide layer and a silicon nitride layer as a hard mask on a germanium or group III-V semiconductor substrate, by using an ion enhanced chemical vapor deposition method;

ii. forming the pattern structure for the source, the drain and the fine bar connecting the source and the drain in the hard mask, by performing an electron beam lithography process and etching the silicon nitride layer and the silicon oxide layer;

iii. removing a photoresist used in the electron beam lithography process;

iv. anisotropically dry etching the germanium or group III-V substrate, so as to transfer the pattern structure from the hard mask onto the substrate;

b) forming an oxide isolation layer

A main object of this step is to form an oxide layer under the Fin bar and at both sides of the Fin bar on a surface of the substrate, so that this oxide isolation layer can play a role in suppressing a turn-on of a planar transistor in the substrate and preventing a current flowing through the substrate from the source to the drain, thus lowering a leakage current and a power consumption of the device.

Solution 1:

i. depositing a new silicon oxide layer as the oxide isolation layer by using an ion enhanced chemical vapor deposition method;

ii. planarizing the silicon oxide layer by using a chemical mechanical polishing (CMP) process until stopping at a surface of the silicon nitride layer in the hard mask at the top of the Fin bar;

iii. etching back the new deposited silicon oxide layer by using a wet etching method until the Fin bar is exposed to a designed height as a channel region;

Solution 2:

i. depositing a new silicon nitride layer;

ii. etching the new silicon nitride layer by using an anisotropic dry etching method, so as to form silicon nitride sidewalls at both sides of the Fin bar;

iii. etching the germanium or group III-V substrate exposed at both sides of the Fin bar by using an anisotropic dry etching method;

iv. etching the germanium or group III-V substrate exposed and recessed at both sides of the Fin bard and the germanium or group III-V substrate located at the bottom of the Fin bar by using an isotropic dry etching method;

If the germanium or group III-V substrate located at the bottom of the Fin bar is completely etched so that the Fin bar is not connected with the substrate, a short channel effect may be well inhibited; if the germanium or group III-V substrate located at the bottom of the Fin bar is partially etched so that the Fin bar is still connected with the substrate, the device may have a substrate bias effect, and a threshold voltage may easily be designed.

i. depositing a new silicon oxide layer as an oxide isolation layer by using an ion enhanced chemical vapor deposition method;

ii. planarizing the silicon oxide layer by using a chemical mechanical polishing (CMP) process until stopping at a surface of the silicon nitride layer in the hard mask at the top of the Fin bar;

iii. etching back the new deposited silicon oxide layer by using a wet etching method until the Fin bar is exposed to a designed height as a channel region;

c) fabricating a gate structure, a source and a drain structure

A main object of this step is to form the gate structure, wherein the gate structure needs to be defined by an electron beam lithography process. This is mainly because that a width of a gate line may be easily controlled to be about 22 nm by the electron beam lithography process, which is a desired channel length. Moreover, if a chemical mechanical polishing (CMP) process is further performed to separate the gate structure at both sides of the Fin bar into individual parts, a FinFET having separated double gates may be obtained.

i. depositing a gate dielectric layer by ALD;

ii. depositing a gate material layer by PVD;

iii. forming a gate line by performing an electron beam lithography process and etching the gate material layer;

iv. forming a silicon oxide sidewall by performing an ion enhanced chemical vapor deposition and a back-etching process;

v. forming the source and the drain structure by performing an ion implantation process and an annealing process;

In this step, if the gate material layer is planarized by a CMP process before being performed with the lithography process and the planarized surface is a surface of the silicon oxide layer in the hard mask at the top of the Fin bar, two gate lines separated and disconnected with each other are formed at both sides of the Fin bar, so that a multi-threshold voltage device is obtained.

d) forming metal contacts and metal interconnections

A main object of this step is to lead out the source, the drain and the gate, and to facilitate a test and formation of a large-scaled circuit. The present invention has the following technical effects:

The above processes are completely compatible with the conventional silicon-based large scaled integrated circuit fabrication technology, and the fabrication procedure has the characteristics of simple, convenient, and having a short period. Moreover, the FinFET fabricated by the above processes has a minimum width that can be controlled to about 20 nm. The multi-gate structure can provide excellent gate control capacity, and is suitable for fabricating an ultra-short channel device to further reduce the device size. Finally, the FinFET fabricated by the above methods has lower power consumption due to the two following reasons. Firstly, because the oxide layer formed under the Fin bar and at both sides of the Fin bar on the surface of the substrate is used for isolation, a planar transistor in the substrate is inhibited from turning on, and a current is prevented from flowing through the substrate to the drain from the source. Secondly, because the separated double-gate structure may be used to fabricate a field effect transistor with a dynamic threshold voltage, the power consumption can be further reduced while maintaining high performance.

### BRIEF DESCRIPTION OF THE DRAWINGS

FIGS. 1-11 are schematic diagrams showing a process flow for fabricating a FinFET on a germanium or group III-V semiconductor substrate according to the present invention.

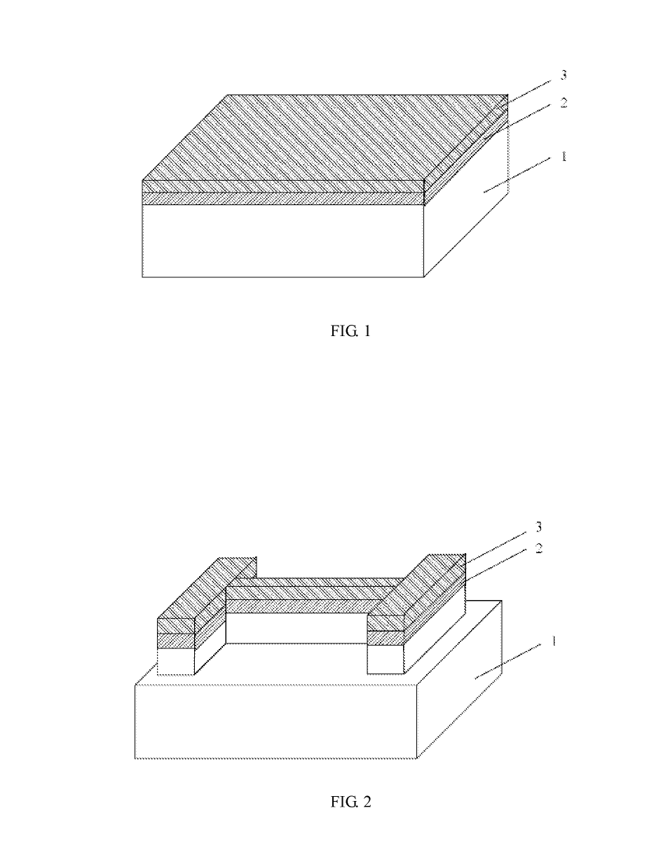

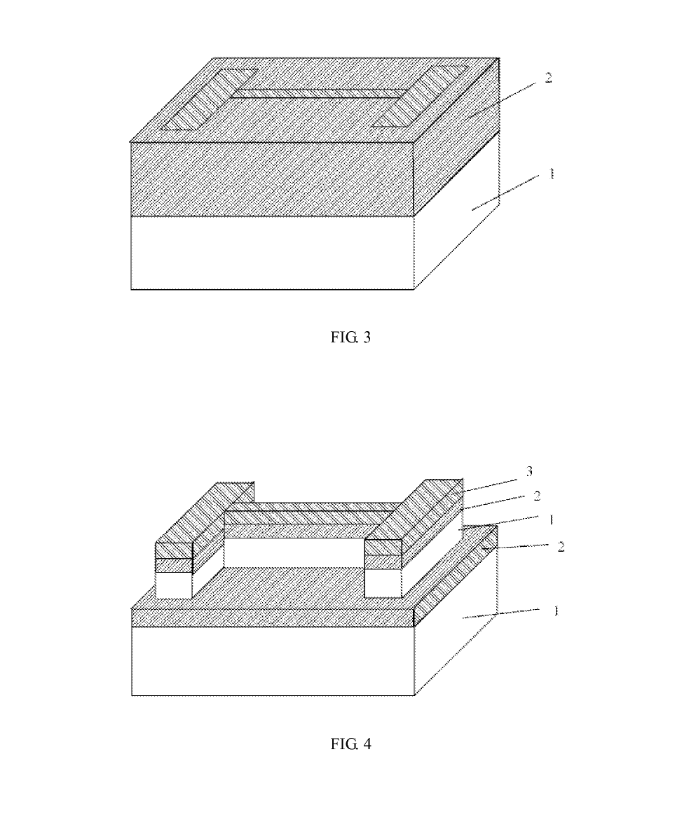

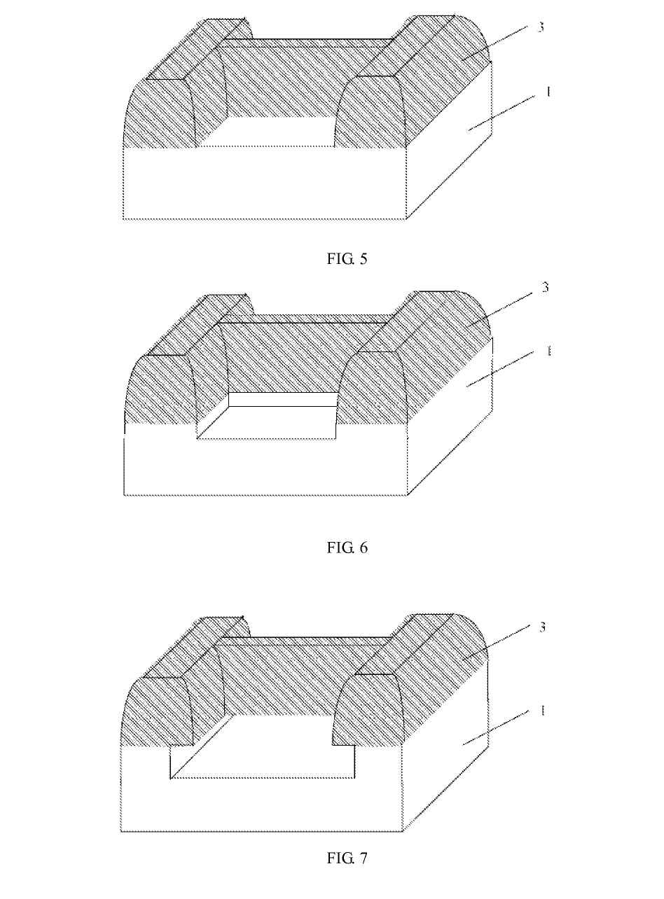

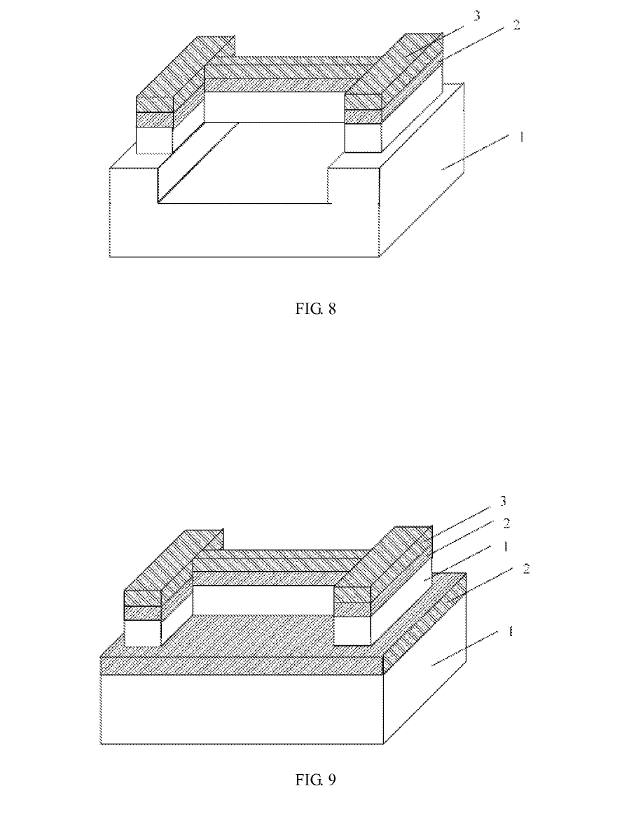

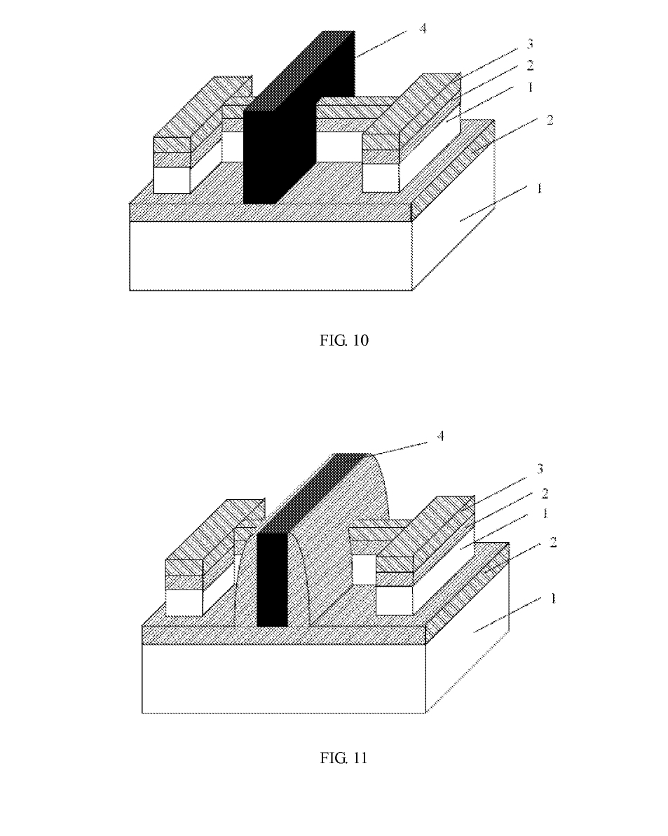

The process flow is briefly described as follow. FIG. 1 is a schematic diagram showing a resultant structure after depositing a silicon oxide film and a silicon nitride film as a hard mask. FIG. 2 is a schematic diagram showing a resultant structure after performing an electron beam lithography method to form a pattern and transferring the pattern onto the germanium or group III-V semiconductor substrate through an anisotropic dry etching method. FIG. 3 is a schematic diagram showing a resultant structure after depositing a silicon oxide layer and performing a CMP process in solution 1. FIG. 4 is a schematic diagram showing a resultant structure after corroding the silicon oxide layer through an isotropic wet etching method until a Fin bar with a certain height is exposed in solution 1. FIG. 5 is a schematic diagram showing a resultant structure after depositing and anisotropically dry etching a silicon nitride layer so as to form silicon nitride sidewalls in solution 2. FIG. 6 is a schematic diagram showing a resultant structure after anisotropically dry etching the germanium or group III-V semiconductor substrate in solution 2. FIG. 7 is a schematic diagram showing a resultant structure after isotropically dry etching the germanium or group III-V semiconductor substrate so as to suspend a Fin bar in solution 2. FIG. 8 is a schematic diagram showing a resultant structure after removing the silicon nitride layer in solution 2. FIG. 9 is a schematic diagram showing a resultant structure after depositing a silicon oxide layer, performing a CMP process and then isotropically wet etching the silicon oxide layer until a Fin bar with a certain height is exposed in solution 2. FIG. 10 is a schematic diagram showing a resultant structure after depositing a gate dielectric layer and a gate material, performing a CMP process and then performing an electron beam lithography process and an anisotropic dry etching to define a gate line. FIG. 11 is a schematic diagram showing a complete structure after performing a sidewall process, a source/drain implantation process and an annealing process.

In the drawings, 1—a germanium or group III-V semiconductor substrate; 2—silicon oxide; 3—silicon nitride; 4—titanium nitride.

### DETAILED DESCRIPTION OF THE EMBODIMENTS

The present invention will be described in more detail by specific embodiments in conjunction with the attached drawings. An example of fabricating a FinFET on a germanium or group III-V semiconductor substrate will be described, but it is not intended to limit the scope of the present invention in any way.

Solution 1: fabricating an n-typed germanium or group III-V FinFET, in which a Fin bar has a thickness of about 20 nm and a channel length of about 32 nm.

1. A silicon oxide layer with a thickness of 300 Å is deposited on a germanium or group III-V semiconductor substrate by an ion enhanced chemical vapor deposition;

2. A silicon nitride layer with a thickness of 1000 Å is deposited on the silicon oxide layer by an ion enhanced chemical vapor deposition, as shown in FIG. 1;

3. A pattern structure for a source, a drain and a fine bar connecting the source and the drain are defined by an electron beam lithography process, wherein a structure of the fine bar has a width of 20 nm;

4. The silicon nitride layer with the thickness of 1000 Å is anisotropically dry etched;

5. The silicon oxide layer with the thickness of 300 Å is anisotropically dry etched;

6. A photoresist is removed;

7. The germanium or group III-V substrate is etched for 1000 Å by an anisotropic dry etching process, so as to transfer the pattern onto the substrate, as shown in FIG. 2;

8. A silicon oxide layer with a thickness of 5000 Å is deposited on the substrate by an ion enhanced chemical vapor deposition;

9. The silicon oxide layer is planarized through a chemical mechanical polishing (CMP) process until stopping at a surface of the silicon nitride layer in the hard mask at the top of a Fin bar, as shown in FIG. 3;

10. The silicon oxide layer is corroded through an isotropic wet etching process until the Fin bar is exposed with a height of 500 Å, as shown in FIG. 4;

11. A surface of the Fin bar is cleaned by using HF solution;

12. A high-K dielectric layer such as HfO₂ with a thickness of 5 nm is deposited through ALD;

13. A titanium nitride layer is sputtered with a thickness of 1000 Å as a gate material;

14. A gate fine line is defined through an electron beam lithography process. The gate line has a width of 32 nm;

15. The titanium nitride layer with the thickness of 1000 Å is etched through an anisotropic dry etching process to form the gate fine line, as shown in FIG. 10;

16. A silicon oxide layer with a thickness of 200 Å is deposited as a sidewall material, through an ion enhanced chemical vapor deposition process;

17. The silicon oxide layer with the thickness of 200 Å is anisotropically dry etched to form sidewalls;

18. An ion implantation process for the source/drain is performed to inject As under an implantation energy of 50 keV and an implantation dosage of 4e15 cm⁻²;

19. A RTP annealing is performed at 1050° C. for 5 seconds in an atmosphere of nitrogen, as shown in FIG. 11.

Solution 2: fabricating an n-typed germanium or group III-V FinFET, in which a Fin bar has a thickness of about 30 nm and a channel length of about 32 nm.

1. A silicon oxide layer with a thickness of 300 Å is deposited on a germanium or group III-V semiconductor substrate by an ion enhanced chemical vapor deposition;

2. A silicon nitride layer with a thickness of 1000 Å is deposited on the silicon oxide layer by an ion enhanced chemical vapor deposition, as shown in FIG. 1;

3. A pattern structure for a source, a drain and a fine bar connecting the source and the drain are defined by an electron beam lithography process, wherein a structure of the fine bar has a width of 20 nm;

4. The silicon nitride layer with the thickness of 1000 Å is anisotropically dry etched;

5. The silicon oxide layer with the thickness of 300 Å is anisotropically dry etched;

6. A photoresist is removed;

7. The germanium or group III-V substrate is etched for 1000 Å by an anisotropic dry etching process, so as to transfer the pattern onto the substrate, as shown in FIG. 2;

8. A silicon nitride layer of 500 Å is deposited on the substrate through an ion enhanced chemical vapor deposition;

9. The silicon nitride layer with a thickness of 500 Å is etched through an anisotropic dry etching process, as shown in FIG. 5, so as to form silicon nitride sidewalls at both sides of the Fin bar;

10. The germanium or group III-V substrate is etched by 1000 Å through an anisotropic dry etching process, as shown in FIG. 6, and the germanium or group III-V substrate exposed at both sidewalls of the Fin bar is etched;

11. The germanium or group III-V substrate is etched by 1000 Å through an isotropic dry etching, as shown in FIG. 7, the germanium or group III-V substrate exposed and recessed at both sides of the Fin bar are etched, and the germanium or group III-V substrate located at the bottom of the Fin bar are etched. If the germanium or group III-V substrate located at the bottom of the Fin bar is completely etched so that the Fin bar is disconnected with the substrate, a short channel effect may be well inhibited. If the germanium or group III-V substrate located at the bottom of the Fin bar is partially etched so that the Fin bar is still connected with the substrate, the device may have a substrate bias effect and may easily be designed in respect to a threshold voltage;

12. The silicon nitride layer with the thickness of 1000 Å is removed through an isotropic wet etching, as shown in FIG. 8;

13. The silicon oxide layer with a thickness of 5000 Å is deposited on the substrate through an ion enhanced chemical vapor deposition;

14. The silicon oxide layer is planarized through a chemical mechanical polishing (CMP) process until stopping at a surface of the silicon nitride layer in the hard mask at the top of a Fin bar;

15. The silicon oxide layer is corroded through an isotropic wet etching until the Fin bar is exposed with a height of 500 Å, as shown in FIG. 9;

16. A surface of the Fin bar is cleaned by using HF solution;

17. A high-K dielectric layer such as HfO₂ with a thickness of 5 nm is deposited through ALD;

18. A titanium nitride layer is sputtered with a thickness of 1000 Å as a gate material;

19. A gate fine line is defined through an electron beam lithography process. The gate line has a width of 32 nm;

20. The titanium nitride layer with the thickness of 1000 Å is etched through an anisotropic dry etching process to form the gate fine line, as shown in FIG. 10;

21. A silicon oxide layer with a thickness of 200 Å is deposited as a sidewall material through an ion enhanced chemical vapor deposition;

22. The silicon oxide layer with the thickness of 200 Å is anisotropically dry etched, to form sidewalls;

23. An ion implantation for the source/drain is performed to inject As under an implantation energy of 50 keV and an implantation dosage of 4e15 cm⁻²;

24. A RTP annealing is performed at 1050° C. for 5 seconds in an atmosphere of nitrogen, as shown in FIG. 11.

Finally, it is noted that the disclosure of embodiments is to help further understanding the present invention. However, those skilled in the art can appreciate that various substitutions and modifications can be made without departing from the spirit and scope of the present invention. Therefore, the present invention is not limited to the content disclosed by the embodiments, and the scope of the present invention is defined by the claims.

1. A method for fabricating a FinFET on a germanium or group III-V semiconductor substrate comprising the following steps:
a) forming a pattern structure for a source, a drain and a fine bar connecting the source and the drain
i. depositing a silicon oxide layer and a silicon nitride layer as a hard mask on the germanium or group III-V substrate, by using an ion enhanced chemical vapor deposition method;
ii. forming the pattern structure for the source, the drain and a Fin bar connecting the source and the drain in the hard mask, by performing an electron beam lithography process and etching the silicon nitride layer and the silicon oxide layer;
iii. removing a photoresist used in the electron beam lithography process;
iv. anisotropically dry etching the germanium or group III-V substrate, so as to transfer the pattern structure from the hard mask onto the substrate;
b) forming an oxide isolation layer
i. depositing a new silicon oxide layer as the oxide isolation layer by using an ion enhanced chemical vapor deposition method;
ii. planarizing the silicon oxide layer by using a chemical mechanical polishing (CMP) process until stopping at a surface of the silicon nitride layer in the hard mask at the top of the Fin bar;
iii. etching back the new deposited silicon oxide layer by using a wet etching method until the Fin bar is exposed to a designed height as a channel region;
c) forming a gate structure and a source and a drain structure
i. depositing a gate dielectric layer by ALD;
ii. depositing a gate material layer by PVD;
iii. forming a gate line by performing an electron beam lithography process and etching the gate material layer;
iv. forming a silicon oxide sidewall by performing an ion enhanced chemical vapor deposition and a back-etching process;
v. forming the source and the drain structure by performing an ion implantation process and an annealing process.

2. A method for fabricating a FinFET on a germanium or group III-V semiconductor substrate comprising the following steps:
a) forming a pattern structure for a source, a drain and a fine bar connecting the source and the drain;
i. depositing a silicon oxide layer and a silicon nitride layer as a hard mask on a germanium or group III-V semiconductor substrate, by using an ion enhanced chemical vapor deposition method;
ii. forming the pattern structure for the source, the drain and a Fin bar connecting the source and the drain in the hard mask, by performing an electron beam lithography process and etching the silicon nitride layer and the silicon oxide layer;
iii. removing a photoresist used in the electron beam lithography process;
iv. anisotropically dry etching the germanium or group III-V substrate, so as to transfer the pattern structure from the hard mask onto the substrate;
b) forming an oxide isolation layer
i. depositing a new silicon nitride layer;
ii. etching the new silicon nitride layer by using an anisotropic dry etching method, so as to form silicon nitride sidewalls at both sides of the Fin bar;
iii. etching the germanium or group III-V substrate exposed at both sides of the Fin bar by using an anisotropic dry etching method;
iv. etching the germanium or group III-V substrate exposed and recessed at both sides of the Fin bar by using an isotropic dry etching method, and etching completely or partially the germanium or group III-V semiconductor substrate located at the bottom of the Fin bar;
v. depositing a new silicon oxide layer as the oxide isolation layer by using an ion enhanced chemical vapor deposition method;
vi. planarizing the silicon oxide layer by using a chemical mechanical polishing (CMP) process until stopping at a surface of the silicon nitride in the hard mask at the top of the Fin bar;
vii. etching back the new deposited silicon oxide layer by using a wet etching method until the Fin bar is exposed to a designed height as a channel region;
c) forming a gate structure and a source and a drain structure
i. depositing a gate dielectric layer by ALD;
ii. depositing a gate material layer by PVD;
iii. forming a gate line by performing an electron beam lithography process and etching the gate material layer;
iv. forming a silicon oxide sidewall by performing an ion enhanced chemical vapor deposition and a back-etching process;
v. forming the source and the drain structure by performing an ion implantation process and an annealing process.

3. The method for fabricating the FinFET on the germanium or group III-V semiconductor substrate of claim 1, characterized in that, in the step c), the gate dielectric layer of high-k dielectric and the gate material layer of metal are formed by ALD and PVD, respectively.

4. The method for fabricating the FinFET on the germanium or group III-V semiconductor substrate of claim 1, characterized in that, in the step c), the gate material layer is planarized by a CMP process before being performed with the lithography process, and the planarized surface is a surface of the silicon oxide layer in the hard mask at the top of the Fin bar; two gate lines separated and disconnected with each other are formed at both sides of the Fin bar by the lithography and etching process.

5. The method for fabricating the FinFET on the germanium or group III-V semiconductor substrate of claim 1, characterized in that, in the steps a) and c), the pattern structure for the source, the drain and the fine bar are formed by a lithography process, and the fine gate structure is formed by an electron beam lithography technology.

6. The method for fabricating the FinFET on the germanium or group III-V semiconductor substrate of claim 1, characterized in that, in the steps a) and b), the deposition process uses a PECVD technology.

7. The method for fabricating the FinFET on the germanium or group III-V semiconductor substrate of claim 1, characterized in that, in the step c), the annealing process is a low temperature annealing process, and a temperature for annealing is in a range of 300° C.˜500° C.
